(19) United States
(12) Patent Application Publication
(10) Pub. No.: US 2016/0291079 A1
(43) Pub. Date: Oct. 6, 2016

(54) AUTOMATED TESTING PLATFORM

(71) Applicant: SHENZHEN TOJOIN COMMUNICATION TECHNOLOGY CO., LTD, Shenzhen (CN)

(72) Inventors: Yinhu Li, Shenzhen (CN); Panxi Zhong, Shenzhen (CN); Xinhua Wu, Shenzhen (CN); Zhuming Han, Shenzhen (CN); Xiaomao Bai, Shenzhen (CN); Yunlong Xu, Shenzhen (CN)

(21) Appl. No.: 15/185,054

(22) Filed: Jun. 17, 2016

Related U.S. Application Data
(63) Continuation of application No. PCT/CN2014/076024, filed on Apr. 23, 2014.

(30) Foreign Application Priority Data
Dec. 18, 2013 (CN) 201310698583.5

(51) Int. Cl. G01R 31/28

(52) U.S. Cl. CPC G01R 31/2808

(57) ABSTRACT

The present disclosure provides an automated testing platform including a machine station, a transporting and positioning mechanism, a manipulator actuating mechanism, a test box, a loading and unloading device, a defective product storage unit, a protective cover, and a loading and unloading cart used in conjunction with the loading and unloading device. The transporting and positioning mechanism is installed on the machine station; the transporting and positioning mechanism includes a base plate, sliding rails and a material-taking mechanism; the base plate is provided with a feed port and an outlet port; the base plate is provided with two sliding rails; the material-taking mechanism is movably arranged on the sliding rails; the manipulator actuating mechanism is installed on the machine station; the manipulator actuating mechanism includes a manipulator and an image positioning device; the loading and unloading device is located at the feed port and the outlet port.

### CROSS-REFERENCE TO RELATED APPLICATIONS

The present application is a Continuation application of PCT application No. PCT/CN2014/076024 filed on Apr. 23, 2014, which claims the benefit of Chinese Patent Application No. 201310698583.5 filed on Dec. 18, 2013, the contents of which are hereby incorporated by reference.

### TECHNICAL FIELD

The present disclosure relates to the field of testing, and more particularly to an automated testing platform.

### BACKGROUND

With the development of science and technology as well as higher living standards, labor cost rises. Meanwhile, due to intensified market competition, products are required to have high quality and short production cycle. In face of these problems, automated equipment arises. The automated equipment can automatically complete workflow tasks according to set instructions or programs without any manual intervention. The automated equipment is widely used in manufacturing industries, food production lines, and electronic product packaging production lines, and plays an important role in agriculture, logistics and other industries. The automated equipment usually includes a software control system, an electrical control system,

### SUMMARY

The present disclosure provides an automated testing platform, which has simple structure, low cost and high efficiency of testing.

In order to solve the above technical problem, as one aspect of the present disclosure, an automated testing platform is provided and includes: a machine station, a transporting and positioning mechanism, a manipulator actuating mechanism, a test box, a loading and unloading device, a defective product storage unit, a protective cover, and a loading and unloading cart used in conjunction with the loading and unloading device; wherein the transporting and positioning mechanism is installed on the machine station; the transporting and positioning mechanism comprises a base plate, sliding rails and a material-taking mechanism; the base plate is provided with a feed port and an outlet port; the base plate is provided with two sliding rails; the material-taking mechanism is movably arranged on the sliding rails (220); the manipulator actuating mechanism (300) is installed on the machine station (100); the manipulator actuating mechanism (300) comprises a manipulator (310) and an image positioning device (320); the loading and unloading device (600) is located at the feed port (211) and the outlet port (212); wherein the automated testing platform further comprises: a control device, which is electrically connected with the material-taking mechanism (230), the image positioning device (320) and the test box (400); the control device controls the material-taking mechanism (230) to take one product to be tested from the feed port (211) and transport the product to the base plate (210); according to a positioning signal from the image positioning device (320), the control device controls the manipulator (310) to transport the product transported to the base plate (210) to the test box; according to a testing signal from the test box (400), the control device transports the product in the test box to the defective product storage unit.

Further, the material-taking mechanism (230) comprises a first installation plate (231), a second installation plate (232), a first cylinder (233), second cylinders (234) and first blocks (235); the first cylinder (233) is installed on the first installation plate (231); the second installation plate (232) is installed on an end of the first cylinder (233); the first blocks (235) and the second cylinders (234) are installed on a bottom surface of the second installation plate (232), and are opposite to each other.

Further, the transporting and positioning mechanism (200) further comprises a positioning mechanism (240); the positioning mechanism (240) comprises a third installation plate (241), second blocks (242) and third cylinders (243); the second blocks (242) and the third cylinders (243) are installed on a bottom surface of the third installation plate (241), and are opposite to each other.

Further, the loading and unloading device (600) comprises a first guide rod (610), a first screw rod (620), a stepper motor (630) and an ejector plate (640); the stepper motor (630) is connected with the first screw rod (620); the ejector plate (640) is slidably connected with the first guide rod (610), and is threaded connected to the first screw rod (620).

Further, the loading and unloading cart (700) comprises a body (710), a second guide rod (720), a second screw rod (730), a tray support (740), and a tray clamping mechanism (750); the second guide rod (720) and the second screw rod (730) are vertically installed on the body (710); the tray support (740) is slidably connected with the second guide rod (720), and is threaded connected to the second screw rod (730); the tray clamping mechanism (750) is installed at a top end of the second guide rod (720).

Further, the loading and unloading cart (700) further comprises a magnetic locking mechanism (760); the magnetic locking mechanism (760) comprises a first connection rod (761), a second connection rod (762), a magnetic suction plate (763), a handle bar (764), an installation block (765), and a spring (766); the magnetic suction plate (763) is installed on the first connection rod (761); one end of the second connection rod (762) is connected with the first connection rod (761) through the handle bar (764); a second end of the second connection rod (762) is connected with the installation block (765); the spring (766) surrounds the second connection rod (762), and is located between the installation block (765) and the handle bar (764).

Further, the machine station (100) comprises a magnetic suction block (110) cooperating with the magnetic suction plate (763).

Further, the tray clamping mechanism (750) comprises a frame (751), a mobile pressing block (752), and a pressing plate (753); the frame (751) is connected with the mobile pressing block (752); a sliding slot is defined between the frame (751) and the mobile pressing block (752); the pressing plate (753) is movably arranged in the sliding slot.

Further, the transporting and positioning mechanism (200) further comprises a stepper motor (250), a synchronous belt (260), and a through-beam optical fiber (270); the through-beam optical fiber (270) is installed at the feed port (211) and/or the outlet port (212); the synchronous belt (260) is connected with the material-taking mechanism (230); the stepper motor (250) is connected with and drives the synchronous belt (260).

Further, the defective product storage unit (500) comprises guide rails (510), a tray mounting base (520), a synchronous belt (530) and a stepper motor (540); the tray mounting base (520) is movably mounted on the guide rails (510); the synchronous belt (530) is connected with the tray mounting base (520); the stepper motor (540) is connected with and drives the synchronous belt (530).

In the present disclosure, qualified products and defective products can be distinguished without any need for manual intervention, thereby improving efficiency of testing and distinguishing products, and having advantages such as simple structure and low cost.

### BRIEF DESCRIPTION OF THE DRAWINGS

FIG. 1 is a schematic view of an overall structure of the present disclosure;

FIG. 2 is a schematic view of a new overall structure of the present disclosure with a protective cover;

FIG. 3 is a schematic view of an overall structure of a machine station;

FIG. 4 is a schematic view of a transporting and positioning mechanism;

FIG. 5 is a schematic view of a manipulator actuating mechanism;

FIG. 6 is a schematic view of a test box;

FIG. 7 is a schematic view of a material-taking mechanism in one direction;

FIG. 8 is a schematic view of the material-taking mechanism in another direction;

FIG. 9 is a schematic view of a positioning mechanism;

FIG. 10 is a schematic view of a loading and unloading device;

FIG. 11 is a schematic view of a loading and unloading cart;

FIG. 12 is a schematic view of a magnetic locking mechanism;

FIG. 13 is a schematic view of a tray clamping mechanism;

FIG. 14 is a schematic view of a defective product storage unit.

### DETAILED DESCRIPTION

Embodiments of the present disclosure will be described in details hereinafter in conjunction with the drawings, and the present disclosure may be implemented in a variety of different ways defined and covered by claims.

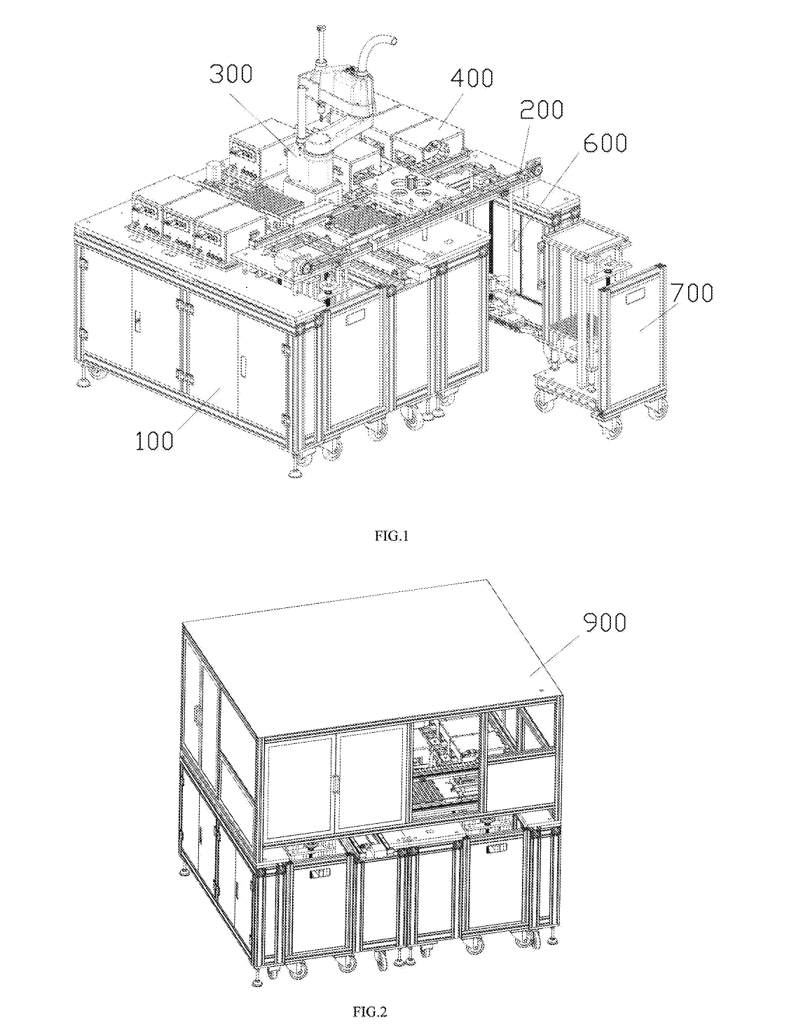

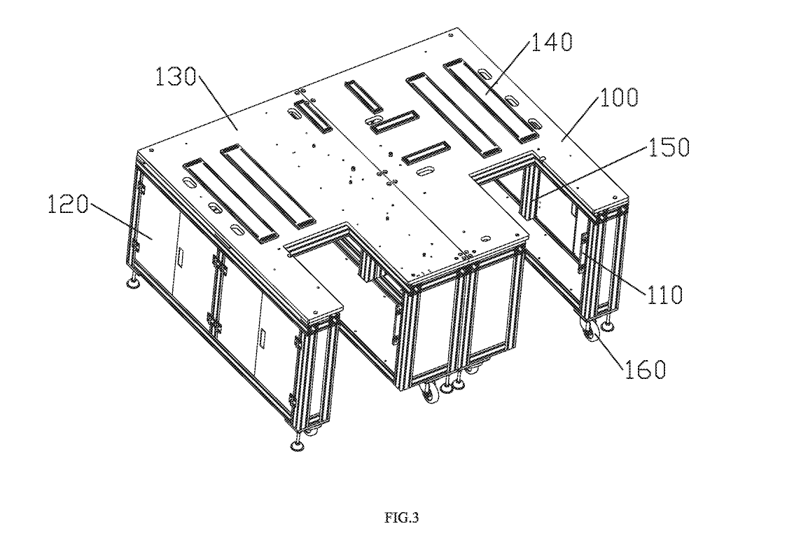

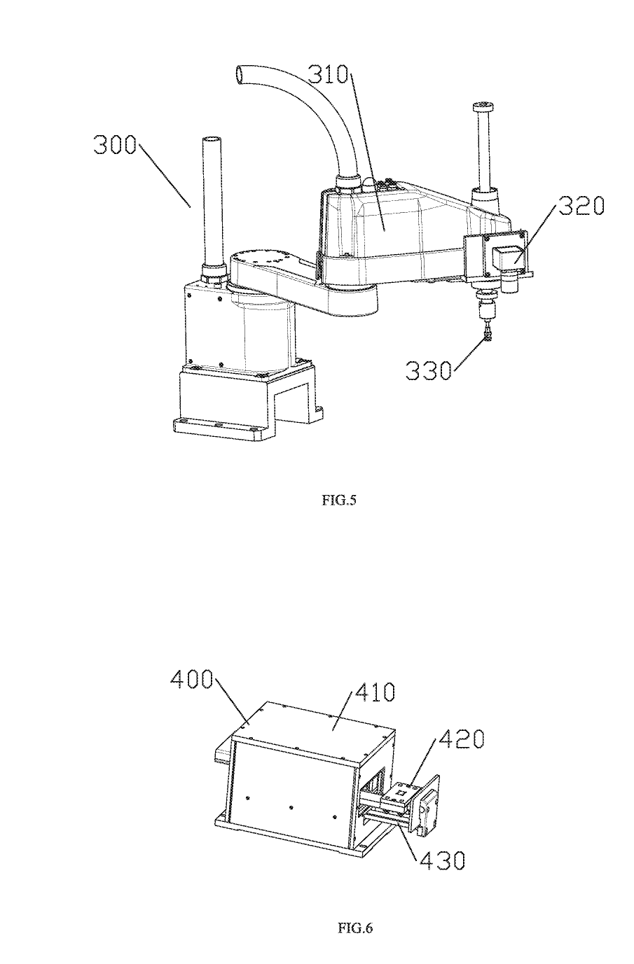

Referring to FIGS. 1-14, the present disclosure provides an automated testing platform, particularly used to test various products such as circuit boards (but not limited to the circuit boards). The automated testing platform includes a machine station 100, a transporting and positioning mechanism 200, a manipulator actuating mechanism 300, a test box 400, a loading and unloading device 600, a defective product storage unit 500, a protective cover 900, and a loading and unloading cart 700 used in conjunction with the loading and unloading device 600. The transporting and positioning mechanism 200 is installed on the machine station 100. The transporting and positioning mechanism 200 includes a base plate 210, sliding rails 220 and a material-taking mechanism 230. The base plate 210 is provided with a feed port 211 and an outlet port 212. The base plate 210 is provided with two sliding rails 220. The material-taking mechanism 230 is movably arranged on the sliding rails 220. The manipulator actuating mechanism 300 is installed on the machine station 100. The manipulator actuating mechanism 300 includes a manipulator 310 and an image positioning device 320. The loading and unloading device 600 is located at the feed port 211 and the outlet port 212. The image positioning device 320 may be a camera, etc., and is configured to determine positions of products through images. Preferably, the manipulator actuating mechanism 300 further includes a nozzle 300 configured to adsorb products. Preferably, the test box 400 includes a box 410, a test tool 420 and a cylinder push rod 430. By the nozzle 300 of the manipulator actuating mechanism 300, one product is placed on the test tool 420 for testing. After completion of the testing, the cylinder push rod 430 pushes the test tool 420 out from the box 410. Then, the product is absorbed by the nozzle 330 and transported away.

The automated testing platform further includes a control device, which is electrically connected with the material-taking mechanism 230, the image positioning device 320 and the test box 400. The control device controls the material-taking mechanism 230 to take one product to be tested from the feed port 211 and transport the product to the base plate 210. According to a positioning signal from the image positioning device 320, the control device controls the manipulator 310 to transport the product transported to the base plate 210 to the test box. According to a testing signal from the test box 400, the control device transports the product in the test box to the defective product storage unit 500.

Referring to FIG. 3, the machine station 100 includes sheet metal doors 120, an installation flat plate 130, an aluminum frame 150, a shielding box installation plate 140 and foot cup casters 160. Preferably, referring to FIG. 1, the machine station 100 further includes a magnetic suction block 110 in cooperation with a magnetic suction plate 763.

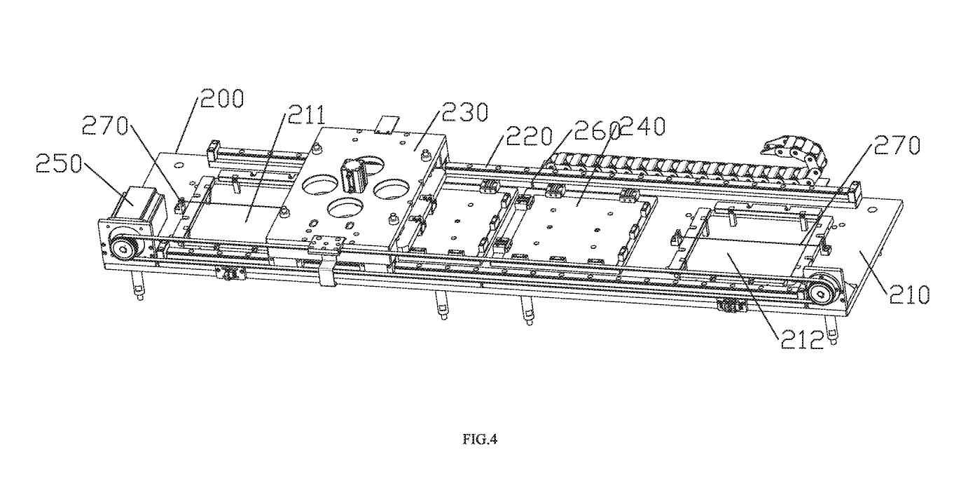

Preferably, referring to FIG. 4, the transporting and positioning mechanism 200 further includes a stepper motor 250, a synchronous belt 260, and a through-beam optical fiber 270. The through-beam optical fiber 270 is installed at the feed port 211 and/or the outlet port 212. The synchronous belt 260 is connected with the material-taking mechanism 230. The stepper motor 250 is connected with and drives the synchronous belt 260. The stepper motor 250 drives the synchronous belt 260 to move, and then the material-taking mechanism 230 is driven to move along the sliding rails 220 in the horizontal direction. The through-beam optical fiber 270 is configured to detect whether there is a tray at the feed port 211 or the outlet port 212, and send a corresponding signal to the control device so as to control a testing process.

When products to be tested are transported to the feed port 211, the products are taken upward out and transported to the base plate 210 by the material-taking mechanism 230. Then, these products are transported to the test box 400 by the manipulator actuating mechanism 300, so that the test box 400 tests these products. After test results come out, a test signal is sent to the control device, and then the control device can control actions of the manipulator actuating mechanism 300 so as to place qualified products on a positioning mechanism 240 at a non-defective product region and place defective products on the defective product storage unit 500. When a tray at the non-defective product region is filled up, the tray is carried to the outlet port 212 by the material-taking mechanism 230, and is stacked on the loading and unloading cart 700. After the loading and unloading cart 700 is filled with the trays, it is prompted by a system to replace the loading and unloading cart to enter the next cycle.

It can be seen, in the present disclosure, qualified products and defective products can be distinguished without any need for manual intervention, thereby improving efficiency of testing and distinguishing products, and having advantages such as simple structure and low cost.

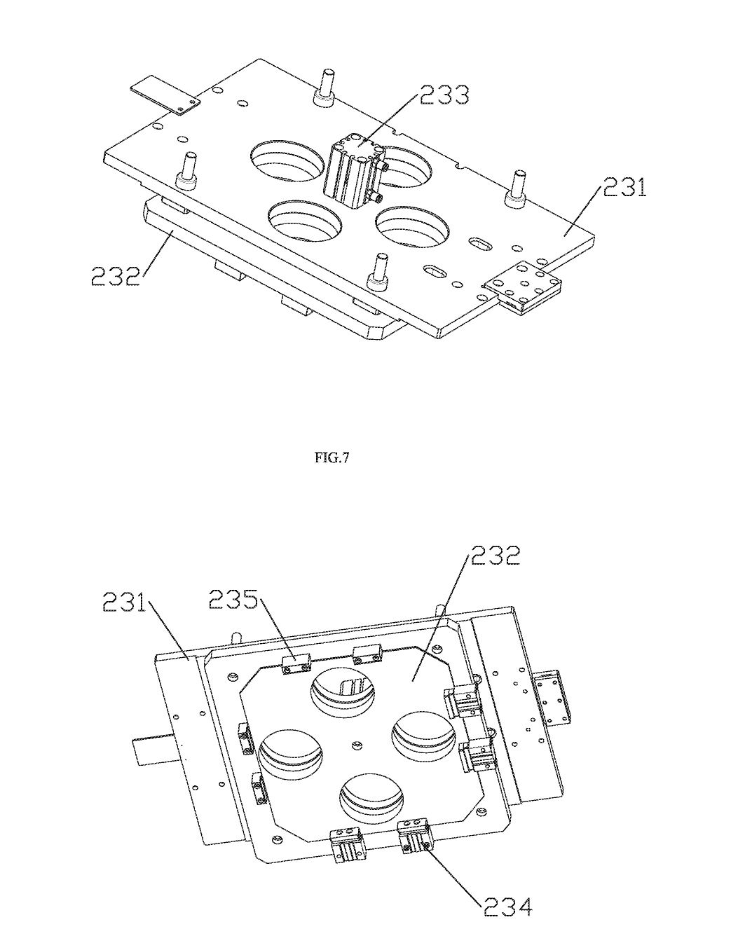

Preferably, referring to FIGS. 7-8, the material-taking mechanism 230 includes a first installation plate 231, a second installation plate 232, a first cylinder 233, second cylinders 234 and first blocks 235. The first cylinder 233 is installed on the first installation plate 231. The second installation plate 232 is installed on an end of the first cylinder 233. The first blocks 235 and the second cylinders 234 are installed on a bottom surface of the second installation plate 232, and are opposite to each other. Under action of the first cylinder 233, the second installation plate 232 can move upward and downward relative to the first installation plate 231. In this way, when products are moved to below the feed port, the second installation plate 232 can move along a direction towards the products. When the second installation plate 232 reaches the products, one tray for the products is located between the first blocks 235 and the second cylinders 234. At this time, when the second cylinders 234 extend, the tray for the products can be clamped between the first blocks 235 and the second cylinders 234. Then, the first cylinder 233 is operated again to be contracted, and the tray for the products can be lifted upward. After that, the material-taking mechanism 230 can move in the horizontal direction under action of the control device, so as to place the tray on a predetermined position for the next step.

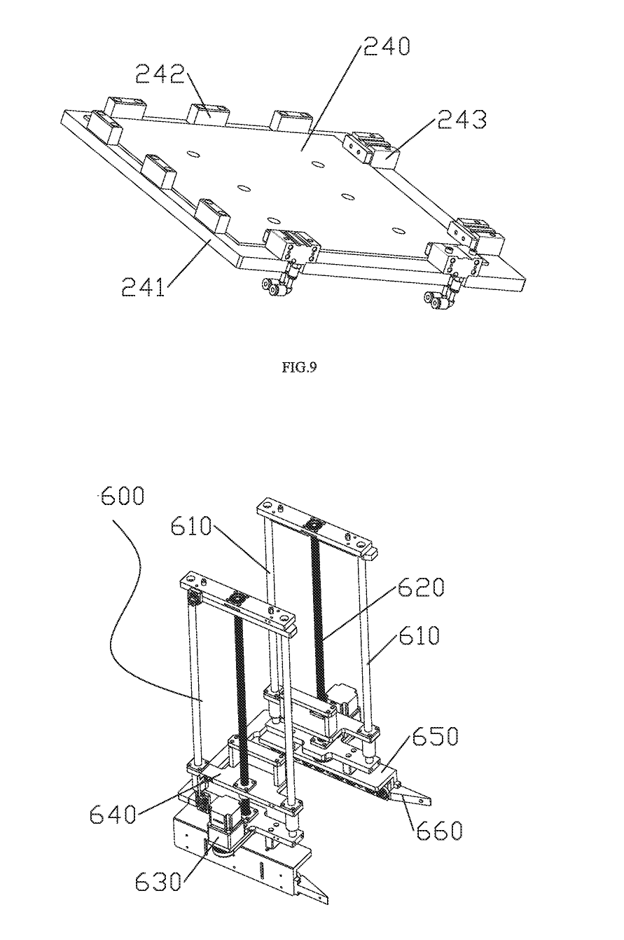

Preferably, referring to FIG. 9, the transporting and positioning mechanism 200 further includes the positioning mechanism 240. The positioning mechanism 240 includes a third installation plate 241, second blocks 242 and third cylinders 243. The second blocks 242 and the third cylinders 243 are installed on a bottom surface of the third installation plate 241, and are opposite to each other. In this embodiment, the material-taking mechanism 230 is disposed on the positioning mechanism 240; at this time, the third cylinders 243 can be operated to extend, so as to clamp and fix the tray between the second blocks 242 and the third cylinders 243, thereby preventing the tray from moving when the manipulator actuating mechanism 300 grabs the tray (grabs products to be tested on the tray).

Preferably, referring to FIG. 10, the loading and unloading device 600 includes a first guide rod 610, a first screw rod 620, a stepper motor 630 and an ejector plate 640. The stepper motor 630 is connected with the first screw rod 620. The ejector plate 640 is slidably connected with the first guide rod 610, and is threaded connected to the first screw rod 620. The control device can control the stepper motor 630 to drive the first screw rod 620 to rotate, so as to drive the ejector plate 640 to move upward, thereby to drive the tray carrying the products to move upward to below the feed port, so that the material-taking mechanism 230 can take the tray upward.

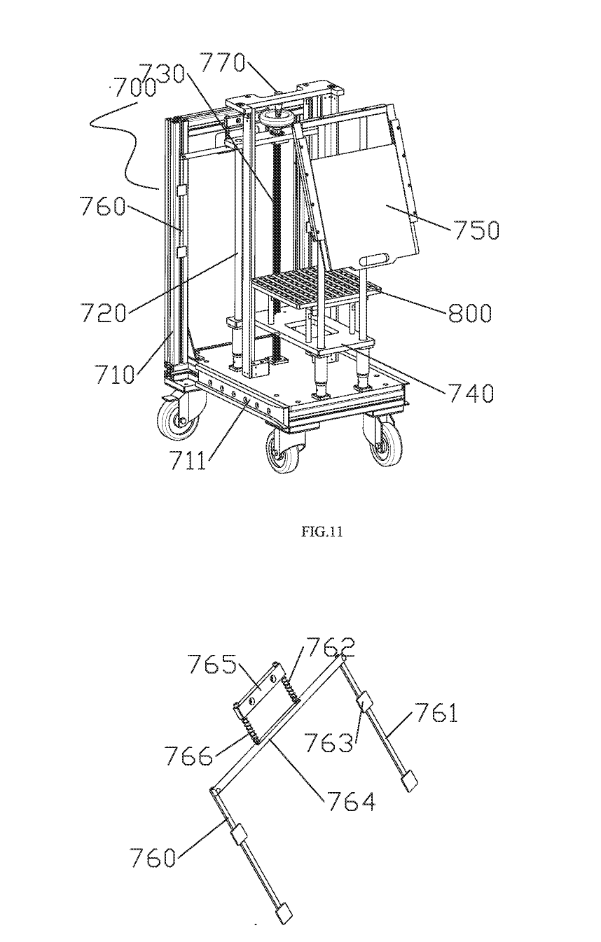

Preferably, referring to FIG. 11, the loading and unloading cart 700 includes a body 710, a second guide rod 720, a second screw rod 730, a tray support 740, and a tray clamping mechanism 750. The second guide rod 720 and the second screw rod 730 are vertically installed on the body 710. The tray support 740 is slidably connected with the second guide rod 720, and is threaded connected to the second screw rod 730. The tray clamping mechanism 750 is installed at a top end of the second guide rod 720. One tray 800 is placed on the tray support 740. Products are placed on the tray support 740. When the products are placed in place, the products can be clamped between the tray support 740 and the tray clamping mechanism 750. Preferably, the loading and unloading cart 700 further includes a hand wheel 770, which is connected with the second screw rod 730 and configured to drive the second screw rod 730, so as to adjust positions of the tray support 740.

Preferably, referring to FIGS. 10-11, the loading and unloading cart 700 is further provided with guide grooves 711. Meanwhile, the loading and unloading device 600 is further provided with installation angle seats 650 and guide wedges 660. Thus, the loading and unloading cart 700 can be accurately pushed into a predetermined position for the loading and unloading device 600 through engagement between the guide wedges 660 and the guide grooves 711.

Preferably, referring to FIG. 12, the loading and unloading cart 700 further includes a magnetic locking mechanism 760. The magnetic locking mechanism 760 includes a first connection rod 761, a second connection rod 762, the magnetic suction plate 763, a handle bar 764, an installation block 765, and a spring 766. The magnetic suction plate 763 is installed on the first connection rod 761. One end of the second connection rod 762 is connected with the first connection rod 761 through the handle bar 764; a second end of the second connection rod 762 is connected with the installation block 765. The spring 766 surrounds the second connection rod 762, and is located between the installation block 765 and the handle bar 764. The loading and unloading cart 700 can be locked through engagement between the magnetic locking mechanism 760 and the magnetic suction block 110 of the machine station 100. When it is required to remove the connection between the two, the handle bar 764 is pulled so as to cause the magnetic suction plate 763 to be staggered with the magnetic suction block 110, thereby separating the two.

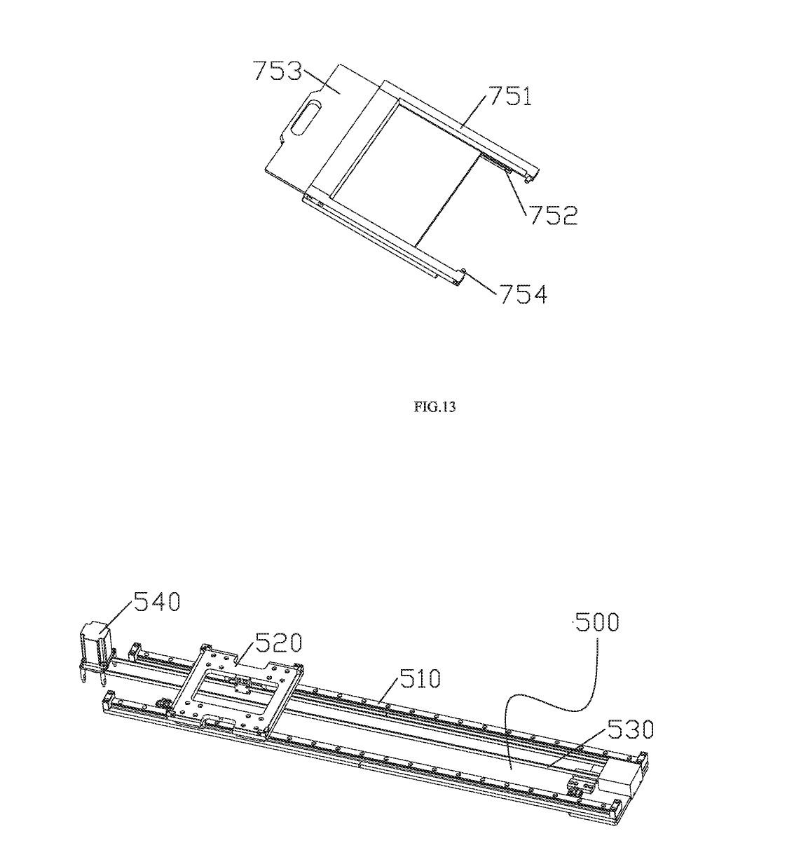

Preferably, referring to FIG. 13, the tray clamping mechanism 750 includes a frame 751, a mobile pressing block 752, and a pressing plate 753. The frame 751 is connected with the mobile pressing block 752. A sliding slot is defined between the frame 751 and the mobile pressing block 752. The pressing plate 753 is movably arranged in the sliding slot. Preferably, the frame 751 is provided with a pivot pin 754, so that the tray clamping mechanism 750 can be rotatably arranged.

Preferably, referring to FIG. 14, the defective product storage unit 500 includes guide rails 510, a tray mounting base 520, a synchronous belt 530 and a stepper motor 540. The tray mounting base 520 is movably mounted on the guide rails 510. The synchronous belt 530 is connected with the tray mounting base 520. The stepper motor 540 is connected with and drives the synchronous belt 530. The control device is connected with the stepper motor 540, and is configured to control the tray mounting base 520 to move along the guide rails 510.

Those described above are preferred embodiments of the present disclosure, and are not used to limit the present disclosure. For those skilled in the art, improvements and substitutions may also be made without departing from the principle of the present disclosure. Those improvements and substitutions should also be considered as the scope of the present disclosure.

What is claimed is:

1. An automated testing platform comprising a machine station, a transporting and positioning mechanism, a manipulator actuating mechanism, a test box, a loading and unloading device, a defective product storage unit, a protective cover, and a loading and unloading cart used in conjunction with the loading and unloading device (600);
wherein the transporting and positioning mechanism is installed on the machine station; the transporting and positioning mechanism comprises a base plate, sliding rails and a material-taking mechanism; the base plate is provided with a feed port and an outlet port; the base plate is provided with two sliding rails); the material-taking mechanism is movably arranged on the sliding rails;
the manipulator actuating mechanism is installed on the machine station; the manipulator actuating mechanism comprises a manipulator and an image positioning device;
the loading and unloading device is located at the feed port and the outlet port;
wherein the automated testing platform further comprises:
a control device, which is electrically connected with the material-taking mechanism, the image positioning device and the test box; the control device controls the material-taking mechanism to take one product to be tested from the feed port and transport the product to the base plate; according to a positioning signal from the image positioning device, the control device controls the manipulator to transport the product transported to the base plate to the test box; according to a testing signal from the test box, the control device transports the product in the test box to the defective product storage unit.

2. The automated testing platform according to claim 1, wherein the material-taking mechanism comprises a first installation plate, a second installation plate, a first cylinder, second cylinders and first blocks; the first cylinder is installed on the first installation plate; the second installation plate is installed on an end of the first cylinder; the first blocks and the second cylinders are installed on a bottom surface of the second installation plate, and are opposite to each other.

3. The automated testing platform according to claim 1, wherein the transporting and positioning mechanism further comprises a positioning mechanism; the positioning mechanism comprises a third installation plate, second blocks and third cylinders; the second blocks and the third cylinders are installed on a bottom surface of the third installation plate, and are opposite to each other.

4. The automated testing platform according to claim 1, wherein the loading and unloading device comprises a first guide rod, a first screw rod, a stepper motor and an ejector plate; the stepper motor is connected with the first screw rod; the ejector plate is slidably connected with the first guide rod, and is threaded connected to the first screw rod.

5. The automated testing platform according to claim 1, wherein the loading and unloading cart comprises a body, a second guide rod, a second screw rod, a tray support, and a tray clamping mechanism; the second guide rod and the second screw rod are vertically installed on the body; the tray support is slidably connected with the second guide rod, and is threaded connected to the second screw rod; the tray clamping mechanism is installed at a top end of the second guide rod.

6. The automated testing platform according to claim 5, wherein the loading and unloading cart further comprises a magnetic locking mechanism; the magnetic locking mechanism comprises a first connection rod, a second connection rod, a magnetic suction plate, a handle bar, an installation block, and a spring; the magnetic suction plate is installed on the first connection rod; one end of the second connection rod is connected with the first connection rod through the handle bar; a second end of the second connection rod is connected with the installation block; the spring surrounds the second connection rod, and is located between the installation block and the handle bar.

7. The automated testing platform according to claim 6, wherein the machine station comprises a magnetic suction block cooperating with the magnetic suction plate.

8. The automated testing platform according to claim 5, wherein the tray clamping mechanism comprises a frame, a mobile pressing block, and a pressing plate; the frame is connected with the mobile pressing block; a sliding slot is defined between the frame and the mobile pressing block; the pressing plate is movably arranged in the sliding slot.

9. The automated testing platform according to claim 1, wherein the transporting and positioning mechanism further comprises a stepper motor, a synchronous belt, and a through-beam optical fiber; the through-beam optical fiber is installed at the feed port and/or the outlet port; the synchronous belt is connected with the material-taking mechanism; the stepper motor is connected with and drives the synchronous belt.

10. The automated testing platform according to claim 1, wherein the defective product storage unit comprises guide rails, a tray mounting base, a synchronous belt and a stepper motor; the tray mounting base is movably mounted on the guide rails; the synchronous belt is connected with the tray mounting base; the stepper motor is connected with and drives the synchronous belt.
